(19) United States
(12) Patent Application Publication
(10) Pub. No.: US 2015/0103589 A1
(43) Pub. Date: Apr. 16, 2015

(54) RESISTIVE MEMORY APPARATUS, OPERATION METHOD THEREOF, AND SYSTEM HAVING THE SAME

(71) Applicant: SK hynix Inc., Gyeonggi-do (KR)

(72) Inventor: Se Ho LEE, Gyeonggi-do (KR)

(73) Assignee: SK hynix Inc., Gyeonggi-do (KR)

(21) Appl. No.: 14/173,542

(22) Filed: Feb. 5, 2014

(30) Foreign Application Priority Data
Oct. 16, 2013 (KR) 10-2013-0123217

(51) Int. Cl. G11C 13/00

(52) U.S. Cl. CPC G11C 13/004; G11C 13/0004; G11C 13/0023
USPC 365/163

(57) ABSTRACT

A resistive memory apparatus includes a memory cell array including a plurality of resistive memory cells, an address decoder suitable for decoding an address signal, and accessing the memory cell array, a read/write control circuit suitable for programming data in the memory cell array or reading out data from the memory cell array, a voltage generation unit suitable for generating a program voltage and a first read voltage for a program operation and a second read voltage for a read operation and providing the voltages to the address decoder, and a controller suitable for controlling the voltage generation unit to generate the first read voltage for verification of the program operation in response to a program command, and the second read voltage higher than the first voltage in response to a read command.

### CROSS-REFERENCES TO RELATED APPLICATION

This application claims priority under 35 U.S.C. 119(a) to Korean application No. 10-2013-0123217, filed on Oct. 16, 2013, in the Korean intellectual property Office, which is incorporated by reference in its entirety as set forth in full.

### BACKGROUND

1. Technical Field

Various exemplary embodiments of the inventive concept relate to a semiconductor device/apparatus, and more particularly, to a resistive memory apparatus, an operation method thereof, and a system having the same

2. Related Art

There is ongoing demand for memory devices, which have nonvolatile properties and repeatedly perform read/write operations, and thus, research is being conducted on such memory devices.

Resistive memory apparatuses are emerged as one of research results. Typical examples of the resistive memory apparatuses include phase-change random access memory (PCRAM) using a chalcogenide compound, ferroelectric RAM (FRAM) using a ferroelectric capacitor, magnetic RAM (MRAM) using a magnetic tunneling effect, resistive RAM (ReRAM) using transition metal oxide, or magnetoresistive RAM using perovskite.

In general, the PCRAM includes a resistor device for data storage and an access device. When the access device is driven through a word line to program data, a program current is applied to the resistor device from a bit line and a resistance state of the resistor device may be changed to a crystalline state (a low-resistance state) or an amorphous state (a high-resistance state).

Resistance of a phase-change material constituting the resistor device is increased due to various causes, and this is called resistance drift. As a resistance value of the phase-change material is increased, the resistance drift intensifies.

FIG. 1 is a view explaining change in data state distribution of a multilevel PCRAM.

A memory cell that may store two bits or more is called a multilevel cell (MLC), and the MLC in the PCRAM further has an intermediate state between the amorphous state (RESET) and the crystalline state (SET).

FIG. 1 illustrates data state distribution (that is, resistance value distribution) of an MLC that stores data of four levels R1, R2, R3, and R4. In FIG. 1, a cell distributed on the right of the x-axis has a high-resistance state than another on the left. The resistance states of the cell may be discriminated by a plurality of reference resistance Ref1, Ref2, and Ref3.

The distributions indicated by solid lines are distribution curves just after PCRAM cells are programmed. Resistance states of the cell are changed by the resistance drift, and the distribution curves are changed as indicated by dotted lines after a predetermined period of time elapses.

In particular, the resistance drift becomes serious as memory cells have high-resistance states R2 and R3, and in parts of the memory cells having a resistance of the R2 level, the resistance level exceeds the reference resistance Ref3 and the resistance state is drifted. Therefore, when a read operation is performed by applying the reference resistance Ref3, data may not be properly read out from the memory cell in which the resistance value is changed and the resistance level exceeds the reference resistance Ref3.

FIG. 2 is a view explaining a relationship between a program resistance and a resistance drift coefficient in a PRAM.

Resistance of the resistor device in a PCRA is changed depending on time as represented by Equation 1.

R(t)=R₀(t/t₀)^{γ} [Equation 1]

Here, t0 denotes a period of time to start of an initial read operation after programming, R0 denotes an initial resistance value, γ denotes a drift coefficient, and t denotes a time interval between t0 and a point of time when a resistance value of the resistor device is read out. That is, the resistance is increased over time after the initial read operation in Equation 1. Increase rate in the resistance is exponentially changed by the drift coefficient.

It can be seen from FIG. 2 that when a memory cell has a low-resistance state R0, the resistance value is not significantly changed even when the drift coefficient is increased. However, it can be seen that when a memory cell has a high-resistance state R2, R3, or R4, the resistance value is sharply changed.

FIGS. 3 and 4 are views explaining a relationship between resistance drift and a data retention time.

FIG. 3 illustrates a relationship between resistance and time depending on a program resistance of a memory cell. In memory cells programmed to a R0 level, after a point F1 of time, a memory cell having a resistance state, which exceeds a first reference resistance Ref1, is detected, thereby causing errors in its read operation. In memory cells programmed to a R1 level, after a point F2 of time, memory cell having a resistance state, which exceeds a second reference resistance Ref2, is detected, thereby causing errors in its read operation. In memory cells programmed to a R2 level after a point F3 of time, a memory cell having a resistance state, which exceeds a third reference resistance Ref3, is detected, thereby causing errors in its read operation. Therefore, in a memory cell that may store all the R0 to R3 levels, reliability of a memory device may not be guaranteed after the point F2 of time which is the fastest time to cause errors.

FIG. 4 illustrates a relationship between current and time depending on a program resistance of a memory cell. The read operation may fail at a point A of time, and then the memory device may not properly operate after the point A of time.

FIG. 5 is a view explaining an operation method of a typical PCRAM.

To store target data in a memory cell, write and read operations for an initial programming and verifying process are performed. The read operation for verification is performed by applying a first read voltage Vc.

Hereafter, even when only the read operation is performed repeatedly on the PCRAM, data stored in a memory cell is read out by applying a voltage Vc having the same level as the first read voltage.

However, as described above, a resistance state of the PCRAM cell is changed over time, and the resistance drift intensifies more in a memory cell programmed in a high-resistance state. Therefore, when data of the memory cell is read out by applying the first read voltage Vc, data of a memory cell of which the resistance distribution changes over the data retention time is read out as a value different from a programmed value.

### SUMMARY

According to an embodiment of the present invention, there is provided a resistive memory apparatus. The resistive memory apparatus may include a memory cell array including a plurality of resistive memory cells, an address decoder suitable for decoding an address signal and accessing the memory cell array, a read/write control circuit suitable for programming data in the memory cell array or reading out data from the memory cell array, a voltage generation unit suitable for generating a program voltage and a first read voltage for a program operation and a second read voltage for a read operation and providing the voltages to the address decoder, and a controller suitable for controlling the voltage generation unit to generate the first read voltage for verification of the program operation in response to a program command, and the second read voltage that is higher than the first voltage in response to a read command.

According to another embodiment of the present invention, there is provided a processor. The processor may include a control unit suitable for generating a control signal including program and read commands in response to a command signal, an operation unit suitable, for performing an operation on data in response to the control signal, and a storage unit suitable for storing the data and including a memory cell array with a plurality of resistive memory cells and a controller suitable for programming the data in the memory cells and verifying the data of the memory cells by a first read voltage in response to the program command and reading out data programmed in the memory cells by a second read voltage that is higher than the first read voltage in response to the read command.

According to further embodiment of the present invention, there is provided a data processing system. The data processing system may include a main controller suitable for decoding a command inputted from an external apparatus to output program and read commands, an interface suitable for exchanging the command and data between the external apparatus and the main controller, a main storage apparatus suitable for storing an application, a control signal, and the data, and an auxiliary storage apparatus suitable for storing a program code or the data. At least one of the main storage apparatus and the auxiliary storage apparatus may including a memory cell array with a plurality of resistive memory cells and a controller suitable for programming the data in the memory cells and verifying the data of the memory cells by a first read voltage in response to the program command and reading out data programmed in the memory cells by a second read voltage that is higher than the first voltage in response to the read command.

According to still further embodiment of the present invention, there is provided an electronic system. The electronic system may include a resistive memory apparatus including a memory cell array with a plurality of resistive memory cells and a controller suitable for programming data in the memory cells and verifying the data of the memory cells by a first read voltage in response to a program command and reading out data programmed in the memory cells by a second read voltage higher than the first voltage in response to a read command, and a memory controller suitable for accessing the resistive memory apparatus by generating the program and read commands in response to request of an external device.

According to still further embodiment of the present invention, there is provided an operation method of a resistive memory apparatus. The operation method may include programming data in a plurality of resistive memory cells of a memory cell array and verifying the data of the memory cells by a first voltage having a first level in response to a program command, and reading out data programmed in the memory cells by a second voltage having a second level that is higher than the first level in response to a read command.

According to still further embodiment of the present invention, there is provided a resistive memory apparatus. The resistive memory apparatus may include a memory cell array including a plurality of resistive memory cells, an address decoder suitable for decoding an address signal, and selecting the memory cells of the memory cell array, a read/write control circuit suitable for programming data in the selected memory cells or reading out data from the selected memory cells, and a controller suitable for controlling the read/write control circuit to verify the data of the selected memory cells using a first voltage when programming the data and reading out the data using a second voltage higher than the first voltage.

These and other features, aspects and embodiments are described below in the section entitled “DETAILED DESCRIPTION”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a view explaining change in data state distribution of a multilevel PCRAM;

FIG. 2 is a view explaining a relationship between a program resistance and a resistance drift coefficient of a PCRAM;

FIGS. 3 and 4 are views explaining a relationship between resistance drift and a data retention time;

FIG. 5 is a view explaining an operation method of a general PCRAM;

FIG. 6 is a view illustrating a configuration of a resistive memory apparatus according to an embodiment of the inventive concept;

FIG. 7 is a view explaining an operation method of a resistive memory apparatus according to an embodiment of the inventive, concept;

FIG. 8 is a view explaining an operation concept of a resistive memory apparatus according to an embodiment of the inventive concept based on a current-voltage characteristic thereof;

FIGS. 9 and 10 are views explaining increase in a data retention time in a resistive memory apparatus according to an embodiment of the inventive concept;

FIG. 11 is a view illustrating a configuration of a processor according to an embodiment of the inventive concept;

FIGS. 12 and 13 are views illustrating configurations of data processing systems according to an embodiment of the inventive concept; and

FIGS. 14 and 15 are views illustrating configurations of electronic systems according to an embodiment of the inventive concept.

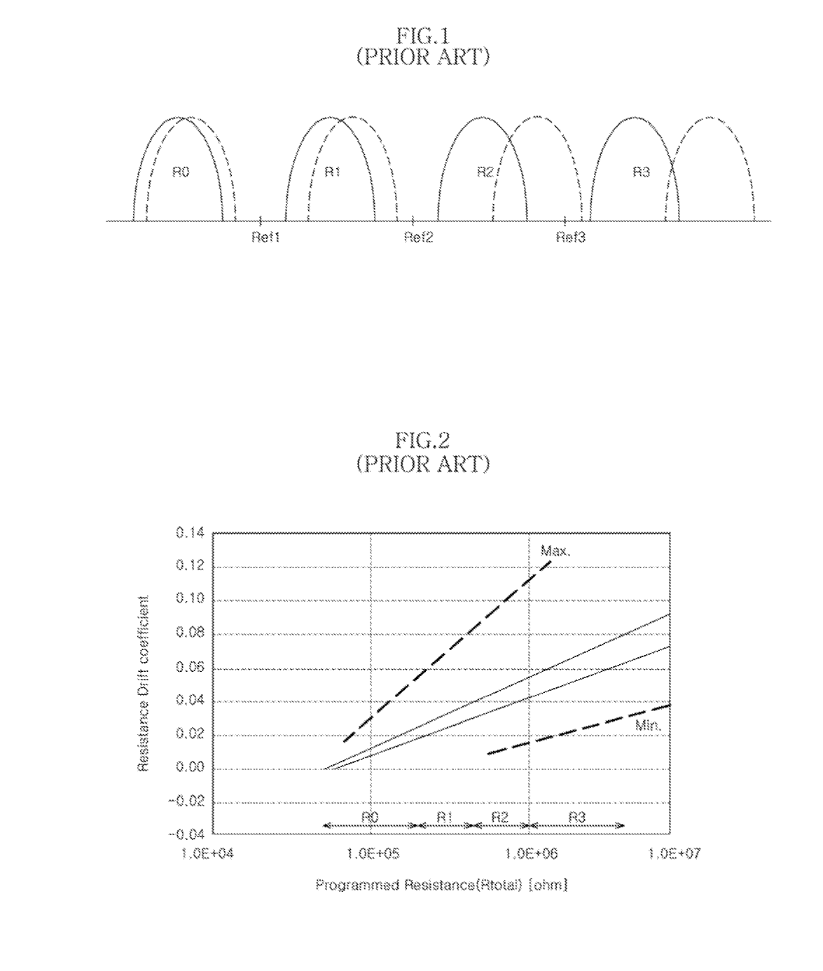

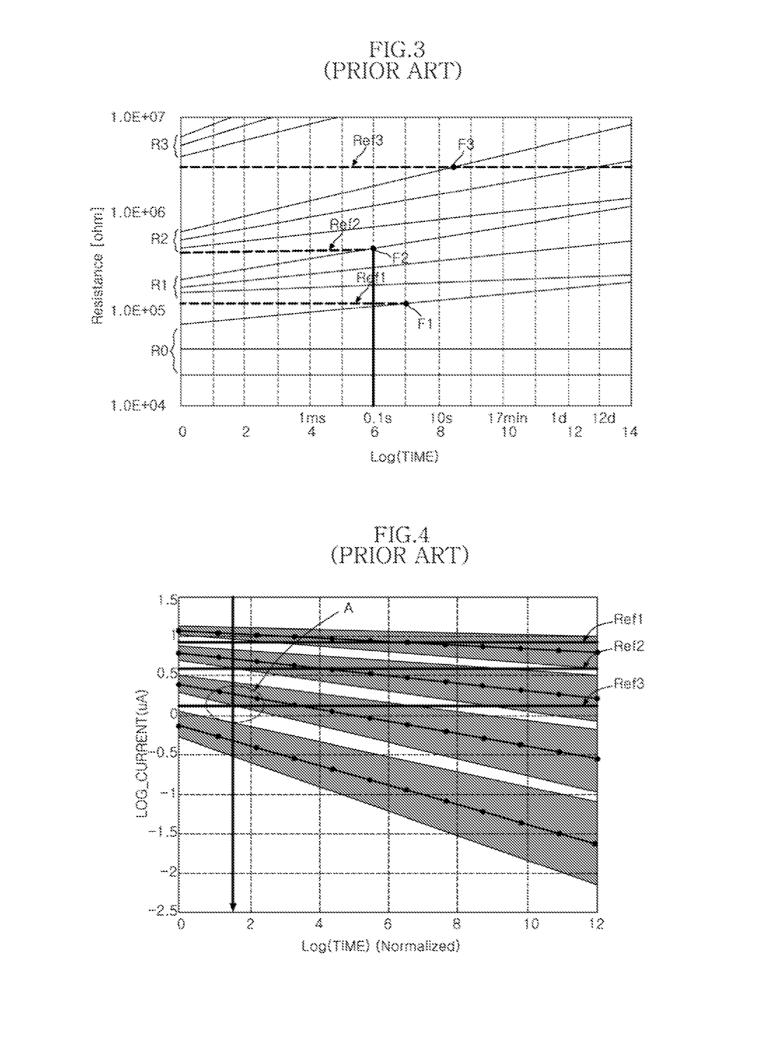

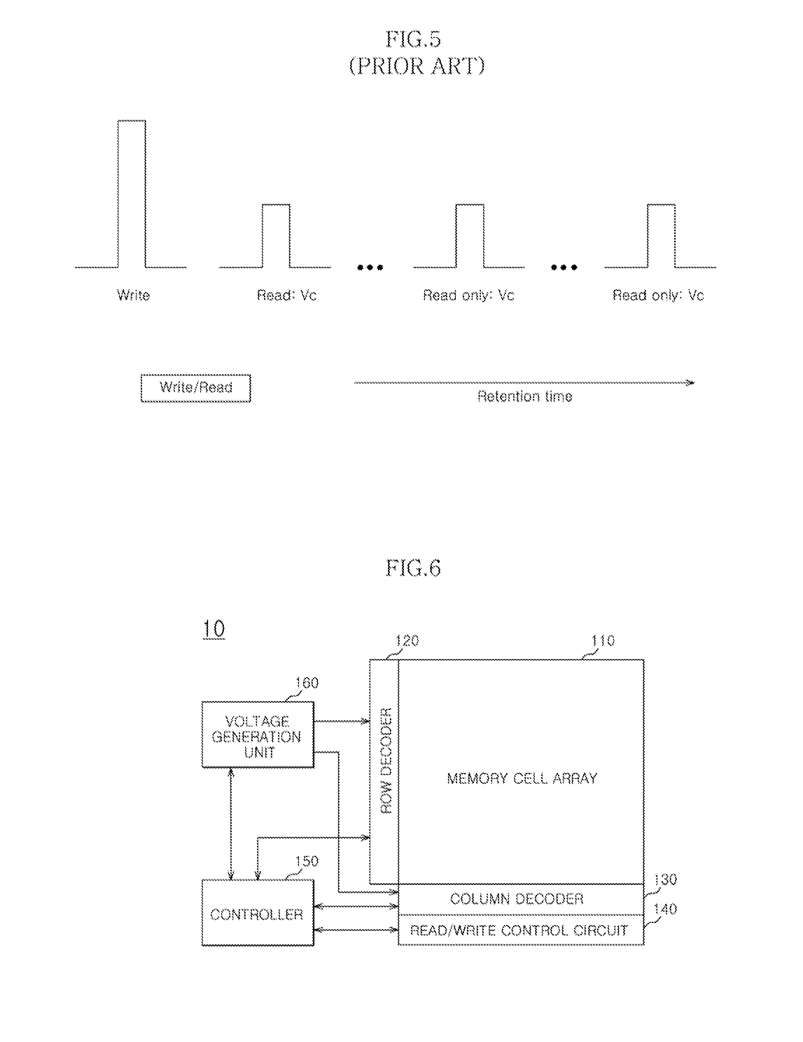

### DETAILED DESCRIPTION

Hereinafter, exemplary embodiments ill be described in greater detail with reference to the accompanying drawings. Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present. It is also noted that in this specification, “connected/coupled” refers to one component not only directly coupling another component but also indirectly coupling another component through an intermediate component. In addition, a singular form may include a plural form as long as it is not specifically mentioned in a sentence.

Although a few embodiments of the inventive concept will be shown and described, it will be appreciated by those of ordinary skill in the art that changes may be made in these exemplary embodiments without departing from the principles and spirit of the inventive concept.

FIG. 6 is a view illustrating a configuration of a resistive memory apparatus according to an embodiment of the inventive concept.

Referring to FIG. 6, a resistive memory apparatus 10 according to an embodiment of the inventive concept may include a memory cell array 110, a row decoder 120, a column decoder 130, a read/write control circuit 140, a controller 150, and a voltage generation unit 160.

The memory cell array 110 may include resistive memory cells arranged in an array form. For examples, the resistive memory cells may be PCRAM cells, MRAM cells, ReRAM cells using transition metal oxide, polymer RAM cells, or memory cells using perovskite, but the resistive memory cells are not limited thereto.

The row decoder 120 and the column decoder 130 are address decoders, and the row decoder 120 and the column decoder 130 receive and decode an external address signal to generate a row address and a column address to access the memory cell array 110, that is, a word line address and a bit line address under control of the controller 150.

The read/write control circuit 140 receives data from a data input/output circuit block (not shown), and programs the data in the memory cell array 110 under control of the controller 150 or provides data read out from a selected memory cell of the memory cell array 110 to the data input/output circuit block under control of the controller 150.

The controller 150 controls the row decoder 120, the column decoder 130, and the read/write control circuit 140 to program data in the memory cell array 110 in response to a program command input from an external apparatus. The programming operation may be performed by a program and verification (PNV) method, and a read voltage for verification may be a voltage having a first level.

The controller 150 controls the row decoder 120, the column decoder 130, and the read/write control circuit 140 to read out data from the memory cell array 110 in response to input of a read command from an external apparatus after an initial programming operation. A read voltage in the read operation may be a voltage having a second level that is higher than the first level.

In a preferred embodiment, the voltage having the second level may be higher than a voltage having the first level and lower than a threshold voltage (a voltage causing phase-change).

The voltage generation unit 160 generates a program voltage, a read voltage for verification, and a read voltage for a read operation and provides the voltages to the row decoder 120, the column decoder 130, and the like under control of the controller 150.

Specifically, a PCRAM among the resistive memory apparatus may be used to replace a flash memory or a storage class memory (SCM). At this time, after data is programmed in a cell once, only a read operation may be performed repeatedly.

Data of a memory cell may be accurately read out by performing a read operation by a second read voltage higher than a first read voltage for verification regardless of resistance drift.

FIG. 7 is a view explaining an operation method of a resistive memory apparatus according to an embodiment of the inventive concept.

For an initial PNV operation, a write operation (program) and a read operation (verification) through a read voltage for verification having a first level Vc are performed. Then, when a read operation is performed, more specifically, when only the read operation is repeatedly performed, the read operation may be performed by applying a read voltage having a second level Va higher than the first level Vc.

The data retention time of the resistive memory apparatus is directly related to the resistance drift. As in the embodiment of the inventive concept, when the read voltage for read is controlled to a level that is higher than the read voltage for verification, the data may be accurately read out even from the cell in which the resistance drift occurs.

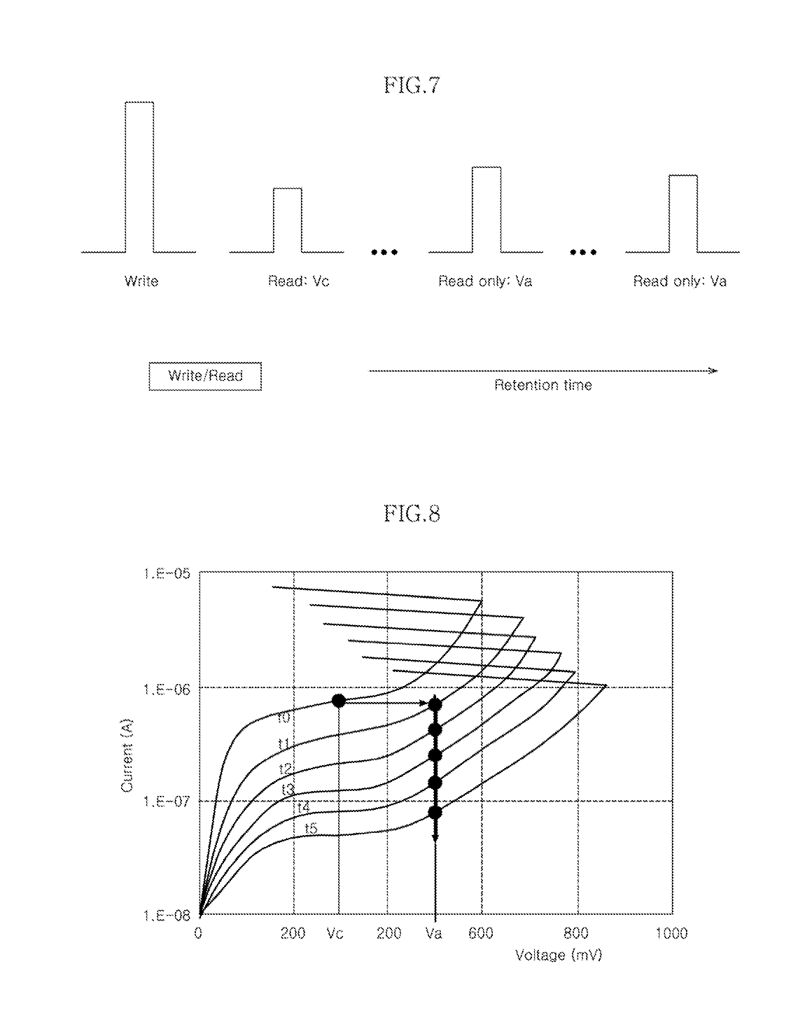

FIG. 8 is a view explaining an operation concept of a resistive memory apparatus according to an embodiment of the inventive concept based on a current-voltage (I-V) characteristic thereof.

A resistive memory cell, specifically, a PCRAM cell has an I-V characteristic as illustrated in FIG. 8. That is, the PCRAM cell has a characteristic in which current flowing through the memory cell is gradually reduced as time elapses from t0 to t5, and this means that the resistance of the memory cell is drifted to increase with time.

Therefore, at a point t0 of time when an initial program operation is performed, the verifying operation may be performed using the read voltage Vc for verification. However, since the resistance of the memory cell is drifted to increase after the point t1 of time, an amount of current flowing in the cell is gradually reduced when the read operation is performed by applying a voltage having the same level as the read voltage Vc for verification. Therefore data of the cell may not be accurately read out.

In the embodiment of the inventive concept, after the initial programming operation, the read operation is performed by applying the voltage Va having a level that is higher than the read voltage Vc for verification. Therefore, a different between an amount of current flowing in the cell in the verifying operation of the initial programming operation and an amount of current flowing in the cell in the read operation may be minimized. That is, although the resistance of the cell is drifted, the amount of current flowing through the cell is maintained to a level similar to a level before the drift. Therefore the data of the cell may be accurately read out.

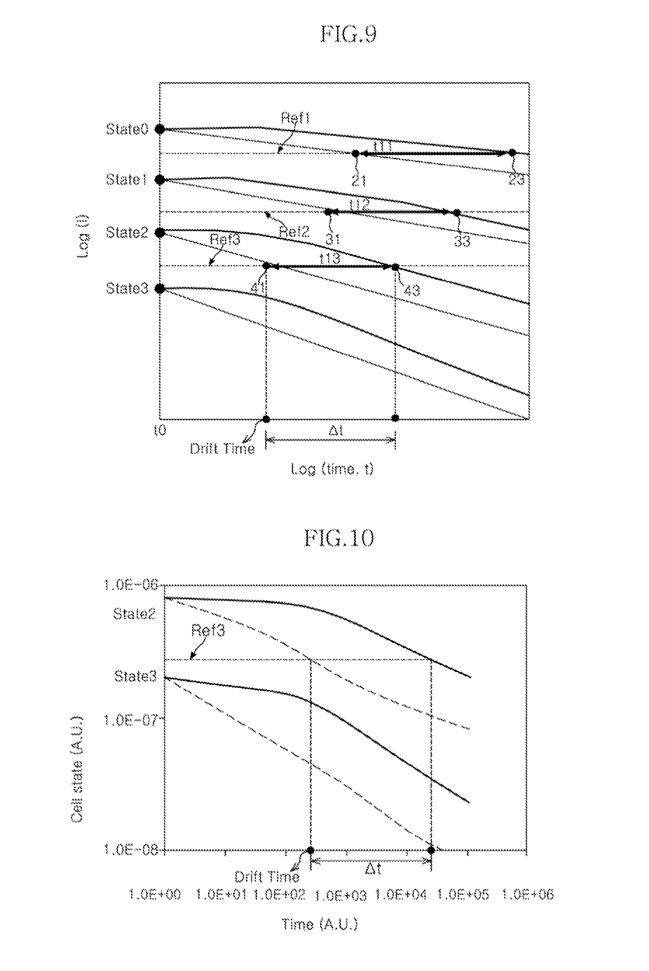

FIGS. 9 and 10 are views explaining increase in a data retention time in a resistive memory apparatus according to an embodiment of the inventive concept.

FIG. 9 is a graph illustrating change in an amount of current of a memory cell over time depending on a resistance state thereof.

When the initial programming operation is performed by the read voltage for verification at the point t0 of time, and the read operation is performed by a voltage having the same level as the read voltage, in a memory cell programmed to have a first resistance state State0, data may not be read out by a first reference voltage Ref1 after a time point 21. Further, in a memory cell having a second resistance state State1, data may not be read out by a second reference voltage Ref2 after a time point 31, and in a memory cell having a third resistance state State2, data may not be read out by a third reference voltage Ref3 after a time point 41.

Since a memory cell having the third resistance state State2 fails the fastest, reliability of the memory cell is not guaranteed after the time point 41.

In an embodiment of the inventive concept, the read operation is performed by a voltage having a level that is higher than the read voltage for verification in the initial programming operation. In the memory cell having the first resistance state State0, data may not be read out after a time point 23. Further, in the memory cell having the second resistance state State1, data may not be read out after a time point 33, and in the memory cell having the third resistance state State2, data may not be read out after a time point 43.

Therefore, the data retention time of the memory cell having the first resistance state State0 is increased by t11, the data retention time of the memory cell having the second resistance state State1 is increased by t12, and the data retention time of the memory cell having the third resistance state State2 is increased by t13.

As a result, the data retention time may be increased by Δt on the basis of the memory cell having the resistance state State2 in which the data retention time is the shortest.

FIG. 10 is a graph illustrating a sensing margin depending on a resistance drift time of memory cells programmed in high-resistance states State2 and State3, in MLCs that store two bits in one cell.

Data of a memory cell having a first high-resistance state State2 and data of a memory cell having a second high-resistance state State3 may be distinguished by the reference voltage Ref3.

In FIG. 10, a curve indicated by a dotted line represents state change of a cell over time when a read operation is performed by applying a read voltage having the same level as the read voltage for verification in the initial programming operation, and a curve indicated by a solid line represents state change of a cell over time when a read operation is performed by a read voltage having a level that is higher than the read voltage for verification in the initial programming operation.

It can be seen from FIG. 10 that when the read voltage having the level higher than the read voltage for verification is applied in the read operation, the drift time at which the resistance state of the cell is drifted based on the reference voltage may be increased by Δt.

FIG. 11 is a view illustrating a configuration of a processor as an example of a system according to an embodiment of the inventive concept.

Referring to FIG. 11, a processor 20 may include a control unit 210, an operation unit 220, a storage unit 230, and a cache memory unit 240.

The control unit 210 receives a signal such as a command or data from an external apparatus, and controls an overall operation of the processor 20 such as decoding of the command, and inputting, outputting, or processing of the data.

The operation unit 220 performs various operations according to a decoding result of the command by the control unit 210. The operation unit 220 may include at least one arithmetic and logic unit (ALU).

The storage unit 230 may function as a register and may be a unit to store data in the processor 20. The storage unit 230 may include a data register, an address register, or a floating point register. Alternatively, the storage unit 230 may include various registers other than the above-described registers. The storage unit 230 may store data to be operated in the operation unit 220, resulting data processed in the operation unit 220, and addresses at which those data are stored.

The storage unit 230 may include, for example, a memory cell array including resistive memory cells, an address decoder, a controller, a voltage generation unit, and the like. In an embodiment of the inventive concept, the storage unit 230 may be the resistive memory apparatus illustrated in FIG. 6. Therefore, the storage unit 230 may program data in the memory cell array by a PNV method in response to input of a program command from the control unit 210, and perform a read operation by a voltage having a level that is higher than a read voltage for verification in the PNV method in response to input of a read command from the control unit 210.

The cache memory unit 240 may function as a temporary storage space.

The processor 20 illustrated in FIG. 11 may be a central processing unit (CPU), a graphic processing unit (GPU), a digital signal processor (DSP), an application processor (AP), or the like of an electronic apparatus.

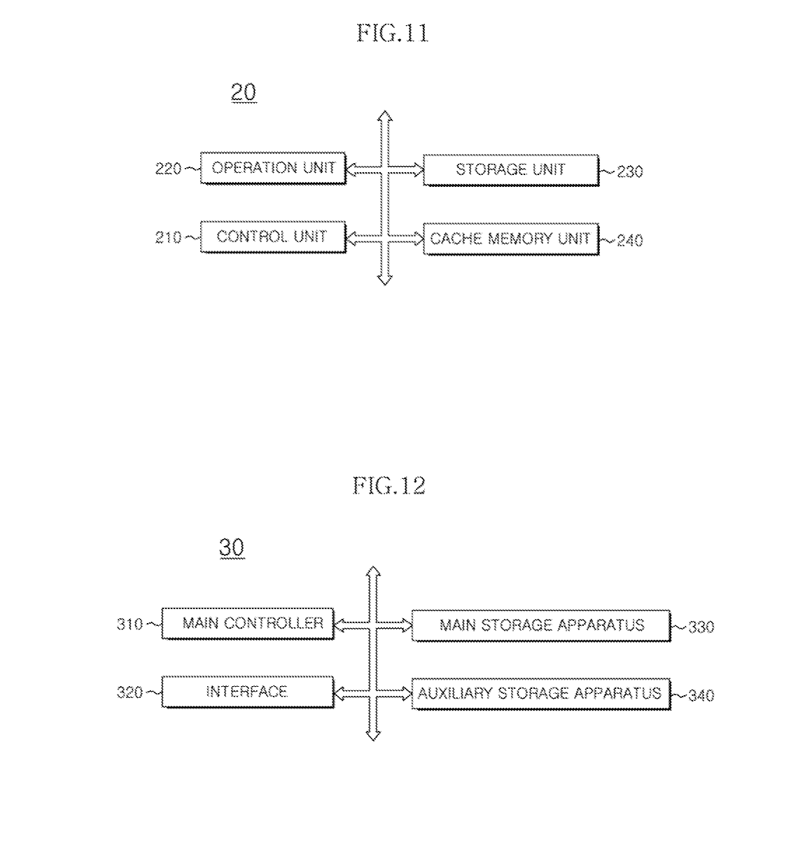

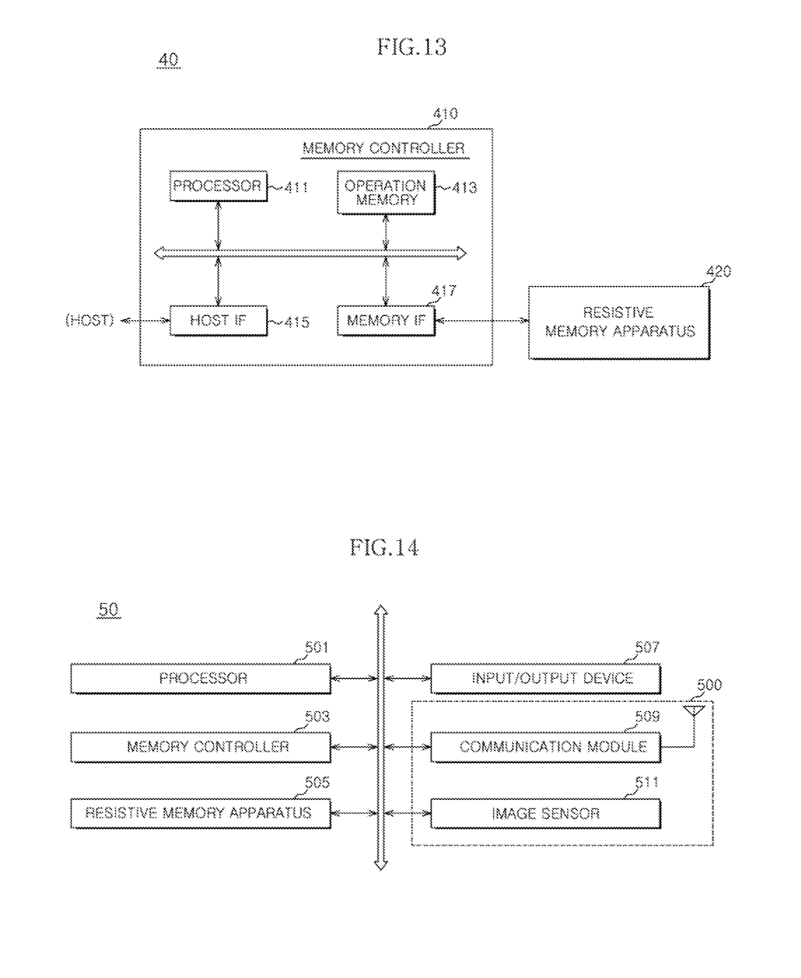

FIGS. 12 and 13 are views illustrating configurations of data processing systems among systems according to an embodiment of the inventive concept.

A data processing system 30 illustrated in FIG. 12 may include a main controller 310, an interface 320, a main storage apparatus 330, and an auxiliary storage apparatus 340.

The data processing system 30 may perform a series of operations for data processing such as input, processing, output, communication, storage, and the like, and the data processing system 30 may be an electronic apparatus such as a computer server, a personal digital assistant (PDA), a portable computer, a web tablet computer, a wireless terminal, a mobile communication terminal, a digital content player, a camera, a global positioning system (GPS), a video camera, a voice recorder, a Telematics device, an audio visual (AV) system, or a smart television.

In another embodiment, the data processing system 30 may be a data storage apparatus, and the data processing system 30 may have a disc form such as a hard disc, an optical drive, a solid state drive, or a digital versatile disc (DVD) or a card form such as a universal serial bus (USB) memory, a secure digital (SD) card, a memory stick, a smart media card, internal/external multimedia cards, or a compact flash card.

The main controller 310 controls exchange of data through the main storage apparatus 330 and the interface 320, and to this end, the main controller 310 controls an overall operation such as decoding of commands inputted through the interface 320 from an external apparatus or operation, comparison, or the like of data stored in the system.

The interface 320 provides an environment for exchange of a command and data between an external apparatus and the data processing system 30. The interface 320 may be a man-machine interface device including an input device (a keyboard, a keypad, a mouse, a voice recognition device, or the like) and an output device (a display, or a speaker), a card interface device, or a disc interface device (Integrated Device Electronics (IDE), a Small Computer System Interface (SCSI), Serial Advanced Technology Attachment (SATA), External SATA (eSATA), or Personal Computer Memory Card International Association (PCMCIA)) depending on an application environment of the data processing system 30.

The main storage apparatus 330 function as a storage place that may store an application, a control signal, data, or the like required for an operation of the data processing system 30, and may execute a program or data transferred from the auxiliary storage apparatus 340. The main storage apparatus 330 may be implemented using a memory apparatus having nonvolatile properties, and for example, the resistive memory apparatus illustrated in FIG. 6 may be used.

The auxiliary storage apparatus 340 may be a space that may retain a program code or data, and may be a high capacity storage apparatus. For example, the auxiliary storage apparatus 340 may be the resistive memory apparatus illustrated in FIG. 6.

That is, for example, the main storage apparatus 330 and or the auxiliary storage apparatus 340 may include a memory cell array including resistive memory cells, an address decoder, a controller, a voltage generation unit, and the like. Therefore, the main storage apparatus 330 and/or the auxiliary storage apparatus 340 may program data in the memory cell array by a PNV method in response to input of a program command from the main controller 310, and perform a read operation by a voltage having a level higher than a read voltage for verification in the PNV method in response to input of a read command from the main controller 310.

A data processing system 40 illustrated in FIG. 13 may include a memory controller 410 and a resistive memory apparatus 420.

The memory controller 410 is configured to access the resistive memory apparatus 420 in response to request of a host, and to this end, the main controller 410 may include a processor 411, an operation memory 413, a host interface 415, and a memory interface 417.

The processor 411 may control an overall operation of the memory controller 410, and the operation memory 413 may store an application, data, a control signal, or the like required for an operation of the memory controller 410.

The host interface 415 performs protocol conversion for exchange of data and a control signal between the host and the memory controller 410, and the memory interface 417 performs protocol conversion for exchange of data and a control signal between the memory controller 410 and the resistive memory apparatus 420.

For example, the resistive memory apparatus 420 may be the resistive memory apparatus illustrated in FIG. 6 and may include a memory cell array including resistive memory cells, an address decoder, a controller, a voltage generation unit, or the like. Therefore, the resistive memory apparatus 420 may program data in the memory cell array by a PNV method in response to input of a program command from the memory controller 410, and perform a read operation by a voltage having a level that is higher than a read voltage for verification in the PNV method in response to input of a read command from the memory controller 410.

The data processing system illustrated in FIG. 13 may be used as a disc apparatus, internal/external memory cards of a portable electronic apparatus, an image processor and other application chipsets.

The operation memory 413 provided in the memory controller 410 may be implemented using the resistive memory apparatus illustrated in FIG. 6.

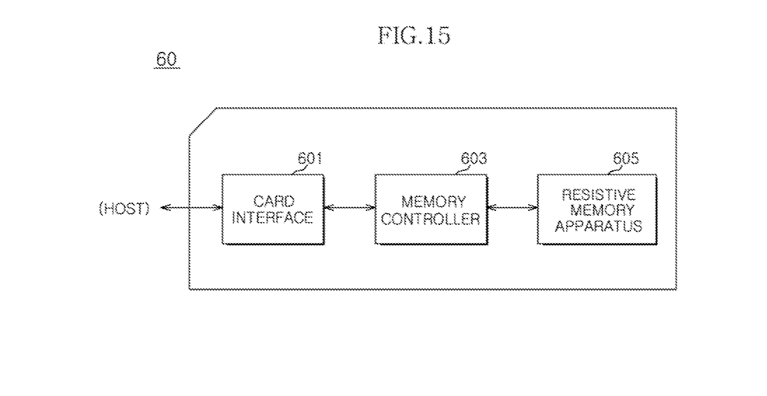

FIGS. 14 and 15 are views illustrating configurations of electronic systems according to an embodiment of the inventive concept.

An electronic system 50 illustrated in FIG. 14 may include a processor 501, a memory controller 503, a resistive memory apparatus 505, an input/output device 507, and a function module 500.

The memory controller 503 may control a data processing operation, for example, a programming operation, a read operation, or the like of the resistive memory apparatus 505 under control of the processor 501.

Data programmed in the resistive memory apparatus 505 may be outputted through the input/output device 507 under control of the processor 501 and the memory controller 503. To this end the input/output device 507 may include a display device, a speaker device, or the like.

The input/output device 507 may further include an input device, and may input a control signal for controlling an operation of the processor 501 or data to be processed by the processor 501 through the input device.

In another embodiment, the memory controller 503 may be implemented as a portion of the processor 501 or a separate chipset from the processor 501.

The resistive memory apparatus 505 may include, for example, a memory cell array including resistive memory cells, an address decoder, a controller, a voltage generation unit, or the like. In an embodiment of the inventive concept, the resistive memory apparatus 505 may be the resistive memory apparatus illustrated in FIG. 6. Therefore, the resistive memory apparatus 505 may program data in the memory cell array by a PNV method in response to input of a program command from the memory controller 503, and perform a read operation by a voltage having a level higher than a read voltage for verification in the PNV method in response to input of a read command from the memory controller 503.

The function module 500 may be a module that may perform a function selected depending on an application example of the electronic system 50 illustrated in FIG. 14, and as an example of the function module 500, a communication nodule 509, and an image sensor 511 are illustrated in FIG. 14.

The communication module 509 provides a communication environment to exchange data and a control signal through connection of the electronic system 50 to a wired or wireless communication network.

The image sensor 511 converts an optical image into digital image signals, and transfers the digital image signals to the processor 501 and the memory controller 503.

When the electronic system 50 of FIG. 14 includes the communication module 509, the electronic system 50 may be a portable communication apparatus such as a wireless communication terminal. When the electronic system 50 of FIG. 14 includes the image sensor 511, the electronic system 50 may be a digital camera, a digital camcorder, or an electronic system (a personal computer (PC), a laptop computer, a mobile communication terminal, or the like) including any one of the digital camera and the digital camcorder.

An electronic system 60 illustrated in FIG. 15 may include a card interface 601, a memory controller 603, and a resistive memory apparatus 605.

The electronic system 60 illustrated in FIG. 15 may be an exemplary example of a memory card or a smart cart, and may include any one of a PCMCIA card, a multimedia card, an embedded multimedia card, a secure digital card, and a USB drive.

The card interface 601 may perform data exchange between a host and the memory controller 603 depending on a protocol of the host. In an embodiment, the card interface 301 may mean hardware that may support a protocol used in the host, software installed in the hardware that may support the protocol used in the host or a signal transmission method.

The memory controller 603 controls data exchange between the resistive memory apparatus 605 and the card interface 601.

The resistive memory apparatus 605 may include the resistive memory apparatus illustrated in FIG. 6. That is, the resistive memory apparatus 605 may include, for example, a memory cell array including resistive memory cells, an address decoder, a controller, a voltage generation unit, or the like. The resistive memory apparatus 605 may program data in the memory cell array by a PNV method in response to input of a program command from the memory controller 603, and perform a read operation by a voltage having a level higher than a read voltage for verification in the PNV method in response to input of a read command from the memory controller 603.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A resistive memory apparatus, comprising:
a memory cell array including a plurality of resistive memory cells;
an address decoder suitable for decoding an address signal and accessing the memory cell array,
a read/write control circuit suitable for programming data in the memory cell array or reading out data from the memory cell array;
a voltage generation unit suitable for generating a program voltage and a first read voltage for a program operation and a second read voltage for a read operation and providing the voltages to the address decoder, and
a controller suitable for controlling the voltage generation unit to generate the first read voltage for verification of the program operation in response to a program command, and the second read voltage that is higher than the first voltage in response to a read command.

2. The resistive memory apparatus of claim 1, wherein the controller controls the read/write control circuit to program the data in the memory cell array using the program voltage and verify the data of the memory cell array using the first read voltage, in response to the program command, and to read out the data programmed in the memory cell array using the second read voltage in response to the read command.

3. The resistive memory apparatus of claim 1, wherein resistance of the resistive memory apparatus is increased after the program operation.

4. The resistive memory apparatus of claim 1, wherein the resistive memory cell is a phase-change random access memory (PCRAM) cell.

5. The resistive memory apparatus of claim 1, wherein the second voltage is higher than the first voltage and lower than a threshold voltage of the resistive memory cell.

6. The resistive memory apparatus of claim 1, wherein the resistive memory cell is a memory cell suitable for at least two bits of data.

7. A processor, comprising:
a control unit suitable for generating a control signal including program and read commands in response to a command signal;
an operation unit suitable for performing an operation on data in response to the control signal; and
a storage unit suitable for storing the data and including a memory cell array with a plurality of resistive memory cells and a controller suitable for programming the data in the memory cells and verifying the data of the memory cells by a first read voltage in response to the program command and reading out data programmed in the memory cells by a second read voltage that is higher than the first read voltage in response to the read command.

8. A data processing system, comprising:
a main controller suitable for decoding a command inputted from an external apparatus to output program and read commands;
an interface suitable for exchanging the command and data between the external apparatus and the main controller;
a main storage apparatus suitable for storing an application a control signal, and the data; and
an auxiliary storage apparatus suitable for storing a program code or the data,
wherein at least one of the main storage, apparatus and the auxiliary storage apparatus including a memory cell array with a plurality of resistive memory cells and a controller suitable for programming the data in the memory cells and verifying the data of the memory cells by a first read voltage in response to the program command and reading out data programmed in the memory cells by a second read voltage that is higher than the first voltage in response to the read command.

9. The data processing system of claim 8, wherein the interface is one of a man-machine interface device, a card interface device, and a disc interface device.

10. An electronic system, comprising:
a resistive memory apparatus including a memory cell array with a plurality of resistive memory cells and a controller suitable for programming data in the memory cells and verifying the data of the memory cells by a first read voltage in response to a program command and reading out data programmed in the memory cells by a second read voltage that is higher than the first voltage in response to a read command; and
a memory controller suitable for accessing the resistive memory apparatus by generating the program and read commands in response to request of an external device.

11. The electronic system of claim 10, wherein the memory controller includes:
a processor suitable for decoding a coma and inputted from a host as the external device;
an operation memory suitable for storing an application, data, and a control signal used for an operation of the memory controller;
a host interface suitable for perform protocol conversion for exchange of data and a control signal between the host and the memory controller; and
a memory interface suitable for performing protocol conversion for exchange of data and a signal between the memory controller and the resistive memory apparatus.

12. The electronic system of claim 10, wherein the memory controller includes:
a processor suitable for decoding a command inputted from the external apparatus;
an operation memory suitable for storing an application, data, and a control signal used for an operation of the memory controller; and
a user interface suitable for providing a data input/output environment between the processor and the external apparatus.

13. The electronic system of claim 12, further comprising a communication module suitable for providing a communication environment for the electronic system to connect to a wired or wireless communication network.

14. The electronic system of claim 12, further comprising an image sensor suitable for converting an optical image into a digital image signal and transferring the digital image signal to the processor.

15. An operation method of a resistive memory apparatus, comprising:
programming data in a plurality of resistive memory cells of a memory cell array and verifying the data of the memory cells by a first voltage having a first level in response to a program command; and
reading out data programmed in the memory cells by a second voltage having a second level higher than the first level in response to a read command.

16. The operation method of claim 15, wherein the second level is higher than the first level and lower than a threshold voltage level of the resistive memory cell.

17. A resistive memory apparatus, comprising:
a memory cell array including a plurality of resistive memory cells;
an address decoder suitable for decoding an address signal and selecting the memory cells of the memory cell array,
a read/write control circuit suitable for programming data in the selected memory cells or reading out data from the selected memory cells; and
a controller suitable for controlling the read/write control circuit to verify the data of the selected memory cells using a first voltage when programming the data and reading out the data using a second voltage higher than the first voltage.
